(19) United States
(12) Patent Application Publication
(10) Pub. No.: US 2025/0098269 A1
(43) Pub. Date: Mar. 20, 2025

(54) INTEGRATED CIRCUIT DEVICE

(71) Applicant: Samsung Electronics Co., Ltd., Suwon-si (KR)

(72) Inventors: Jaehyun CHOI, Suwon-si (KR); Dongsik KONG, Suwon-si (KR); Jihye KWON, Suwon-si (KR); Junsoo KIM, Suwon-si (KR); Junbum LEE, Suwon-si (KR)

(73) Assignee: Samsung Electronics Co., Ltd., Suwon-si (KR)

(21) Appl. No.: 18/762,812

(22) Filed: Jul. 3, 2024

(30) Foreign Application Priority Data
Sep. 20, 2023 (KR) 10-2023-0125854

(51) Int. Cl. H01L 29/423; H01L 29/78; H10B 12/00

(52) U.S. Cl. CPC H10D 64/513; H10B 12/488; H10B 12/50; H10D 30/701

(57) ABSTRACT

An integrated circuit device includes a substrate having formed therein a word line trench extending long in a first horizontal direction, a gate dielectric film covering an inner surface of the word line trench, a word line on the gate dielectric film, the word line filling a lower space of the word line trench and extending long in the first horizontal direction, an insulating capping pattern on the word line, the insulating capping pattern filling an upper space of the word line trench and extending long in the first horizontal direction, and at least one ferroelectric layer arranged at a top portion of the word line and including a first sidewall in contact with the gate dielectric film.

### CROSS-REFERENCE TO RELATED APPLICATION

This application is based on and claims priority under 35 U.S.C. § 119 to Korean Patent Application No. 10-2023-0125854, filed on Sep. 20, 2023, in the Korean Intellectual Property Office, the disclosure of which is incorporated by reference herein in its entirety.

### BACKGROUND

The inventive concepts relate to integrated circuit devices, and more particularly, to integrated circuit devices including a buried word line.

With the increase in the integration density of integrated circuit devices constituting a buried channel array transistor (BCAT), in which a plurality of word lines are buried by a substrate, the pitch of the word lines has decreased and gate induced drain leakage (GIDL) has increased, which may adversely affect the refresh characteristics of the integrated circuit devices.

### SUMMARY

Some example embodiments of the inventive concepts provide an integrated circuit device including a ferroelectric layer at a top portion of a word line.

The inventive concepts are not limited to that mentioned above, and some example embodiments of the inventive concepts that have not been mentioned will be clearly understood by one of skill in the art from the description below.

According to some example embodiments of the inventive concepts, an integrated circuit device may include a substrate having formed therein a word line trench, the word line trench extending longitudinally in a first horizontal direction, the first horizontal direction extending parallel to a main surface of the substrate, a gate dielectric film covering an inner surface of the word line trench, a word line on the gate dielectric film, the word line filling a lower space of the word line trench and extending longitudinally in the first horizontal direction, an insulating capping pattern on the word line, the insulating capping pattern filling an upper space of the word line trench and extending longitudinally in the first horizontal direction, and at least one ferroelectric layer at a top portion of the word line and including a first sidewall in contact with the gate dielectric film.

According to some example embodiments of the inventive concepts, an integrated circuit device may include a substrate including a cell array region and a peripheral circuit region, a plurality of active regions defined by an isolation film, the plurality of active regions including a plurality of first active regions in the cell array region and a plurality of second active regions in the peripheral circuit region, a word line trench extending longitudinally in a first horizontal direction across the plurality of first active regions, the first horizontal direction extending parallel to a main surface of the substrate, a gate dielectric film covering an inner surface of the word line trench, a word line on the gate dielectric film, the word line filling a lower space of the word line trench and extending longitudinally in the first horizontal direction, an insulating capping pattern on the word line, the insulating capping pattern filling an upper space of the word line trench and extending longitudinally in the first horizontal direction, and at least one ferroelectric layer at a top portion of the word line, the at least one ferroelectric layer including a first sidewall in contact with the gate dielectric film.

According to some example embodiments of the inventive concepts, an integrated circuit device may include a substrate having formed therein a word line trench, the word line trench extending longitudinally in a first horizontal direction, the first horizontal direction extending parallel to a main surface of the substrate, a gate dielectric film covering an inner surface of the word line trench, a word line on the gate dielectric film, the word line filling a lower space of the word line trench, extending longitudinally in the first horizontal direction, and including a lower conductive plug and an upper conductive plug on the lower conductive plug, an insulating capping pattern on the upper conductive plug, the insulating capping pattern filling an upper space of the word line trench and extending longitudinally in the first horizontal direction, and a ferroelectric layer between the upper conductive plug and the gate dielectric film. The ferroelectric layer may include a first ferroelectric layer and a second ferroelectric layer spaced apart from the first ferroelectric layer by a certain distance in a second horizontal direction, the second horizontal direction extending parallel to the main surface of the substrate and perpendicular to the first horizontal direction. Each of the first ferroelectric layer and the second ferroelectric layer may include a first sidewall and a second sidewall, the first sidewall in contact with the gate dielectric film, the second sidewall opposite to the first sidewall in the second horizontal direction and in contact with the upper conductive plug. A top surface of each of the first ferroelectric layer and the second ferroelectric layer may be in contact with the insulating capping pattern, and a bottom surface of each of the first ferroelectric layer and the second ferroelectric layer is in contact with the lower conductive plug.

### BRIEF DESCRIPTION OF THE DRAWINGS

Embodiments will be more clearly understood from the following detailed description taken in conjunction with the accompanying drawings in which:

FIG. 1A is a layout diagram illustrating an integrated circuit device according to some example embodiments;

FIG. 1B is an enlarged layout diagram of a region A in FIG. 1A;

FIG. 2 is a cross-sectional view illustrating some elements of a cross-section taken along line X1-X1′ in FIG. 1B;

FIG. 3 is a cross-sectional view illustrating some elements of a cross-section taken along line X2-X2′ in FIG. 1B;

FIG. 4 is a cross-sectional view illustrating some elements of a cross-section taken along line Y1-Y1′ in FIG. 1B;

FIGS. 5A and 5B are enlarged cross-sectional views of a region EX1 in FIG. 4;

FIG. 5C is an enlarged cross-sectional view illustrating some elements of a cross-section taken along line X3-X3′ in FIG. 1B;

FIGS. 6A and 6B are enlarged cross-sectional views of a region EX2 in FIG. 5A; and

FIGS. 7, 8, 9, 10, 11, 12, 13, 14, and 15 are cross-sectional views of sequential stages in a method of manufacturing an integrated circuit device, according to embodiments, and correspond to the cross-section taken along line Y1-Y1′ in FIG. 1B.

### DETAILED DESCRIPTION

Hereinafter, some example embodiments are described in detail with reference to the accompanying drawings. In the drawing, like reference characters denote like elements, and redundant descriptions thereof will be omitted.

In order to clearly describe the present inventive concepts, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present inventive concepts are not necessarily limited to those illustrated in the drawings.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on,” “below,” or “above” another element, it can be directly on the other element or intervening elements may also be present. In contrast, when an element is referred to as being “directly on” another element, there are no intervening elements present. Further, in the specification, the word “on” means positioned above, below, or horizontally adjacent to the object portion, and does not necessarily mean positioned on the upper side of the object portion based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values or shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “apart,” “arranged apart,” or “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “apart,” “arranged apart,” or “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

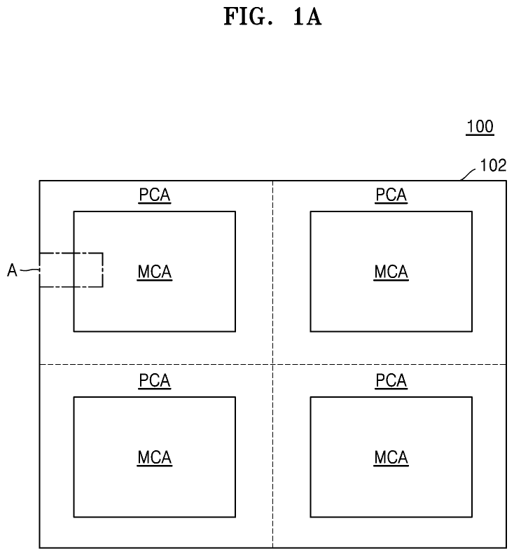

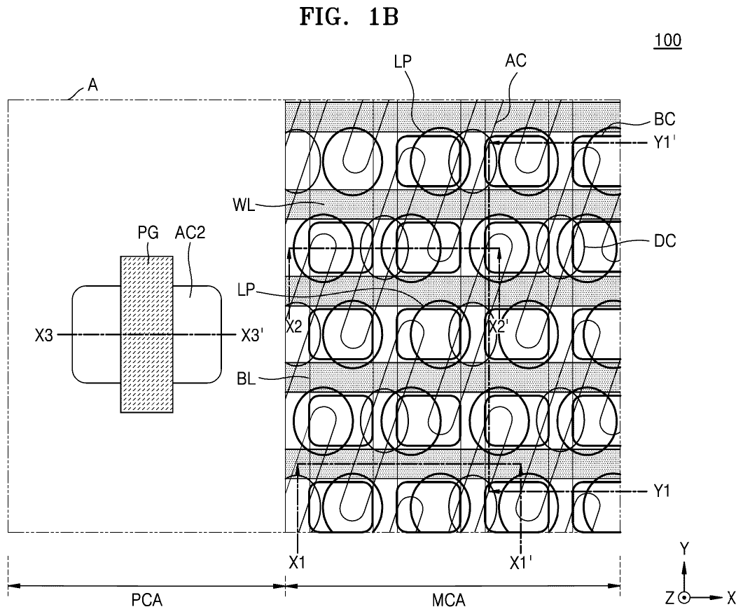

FIG. 1A is a layout diagram illustrating an integrated circuit device 100 according to some example embodiments.

FIG. 1B is an enlarged layout diagram of a region A in FIG. 1A.

Referring to FIGS. 1A and 1B, the integrated circuit device 100 may include a substrate 102, which includes a cell array region MCA and a peripheral circuit region PCA. The cell array region MCA may correspond to a memory cell region of a dynamic random access memory (DRAM) device and the peripheral circuit region PCA may correspond to a core region or peripheral circuit region of the DRAM device. For example, the peripheral circuit region PCA may include a peripheral circuit transistor PG, which transfers a signal and/or power to a memory cell array in the cell array region MCA. In some example embodiments, the peripheral circuit transistor PG may form various circuits, such as a command decoder, a control logic, an address buffer, a row decoder, a column decoder, a sense amplifier, and a data input/output circuit. The peripheral circuit region PCA may include a plurality of peripheral circuit transistors PG.

The integrated circuit device 100 may include a plurality of active regions AC, which extend long (e.g., have a respective longitudinal axis extending) in a diagonal direction to a first horizontal direction (the X direction) and a second horizontal direction (the Y direction) on an X-Y plane. A plurality of word lines WL may extend long in the first horizontal direction (the X direction) across the active regions AC. As described herein, an element, structure or the like that is described to “extend long” in a given direction will be understood that having a longitudinal axis (e.g., the axis of the longest dimension of the element, structure, or the like) that extends in the given direction, such that the element, structure, or the like may be referred to interchangeably as extending longitudinally in the given direction whereby the longitudinal axis of the element extends along, parallel to, and/or the given direction. Each of the word lines WL may have a uniform or substantially uniform width (e.g., constant or substantially constant) in the first horizontal direction (the X direction) that is a length direction (e.g., a direction extending parallel to the longitudinal axes of the word lines WL). The first horizontal direction (the X direction) may extend parallel to a main surface 102M of the substrate 102, which may be an upper surface of the substrate 102. The second horizontal direction (the Y direction) may extend parallel to the main surface 102M of the substrate 102 and may extend perpendicular to the first horizontal direction (the X direction).

A plurality of bit lines BL may extend in the second horizontal direction (the Y direction) above the word lines WL and may be parallel with each other (e.g., may extend in parallel with each other). The bit lines BL may be connected to the active regions AC through direct contacts DC.

A plurality of buried contacts BC may be between two adjacent bit lines BL. A plurality of conductive landing pads LP may be above the buried contacts BC. The buried contacts BC and the conductive landing pads LP may connect the active regions AC to lower electrodes (not shown) of capacitors, which are formed on the bit lines BL. Each of the conductive landing pads LP may at least partially overlap one of the buried contacts BC.

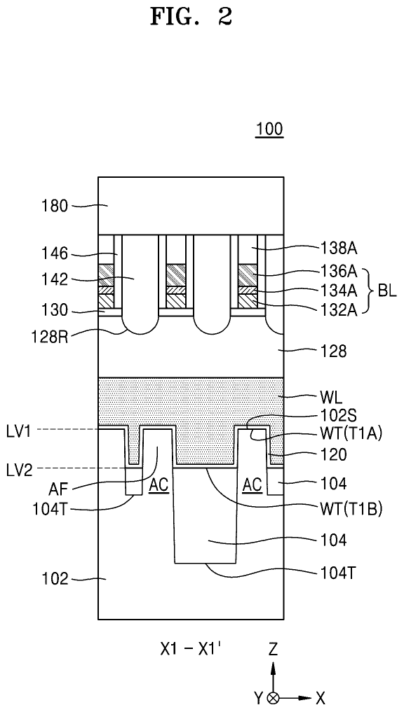

FIG. 2 is a cross-sectional view illustrating some elements of a cross-section taken along line X1-X1′ in FIG. 1B.

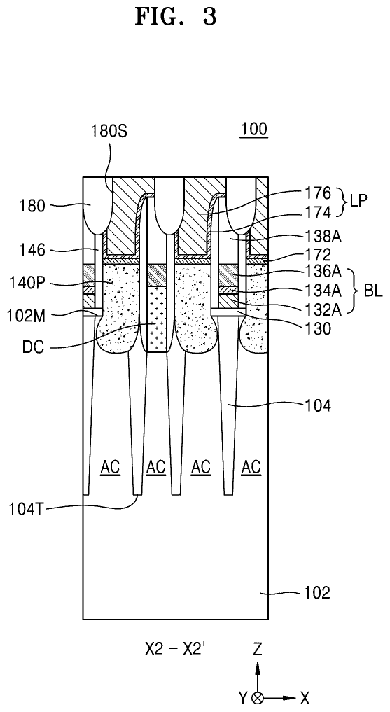

FIG. 3 is a cross-sectional view illustrating some elements of a cross-section taken along line X2-X2′ in FIG. 1B.

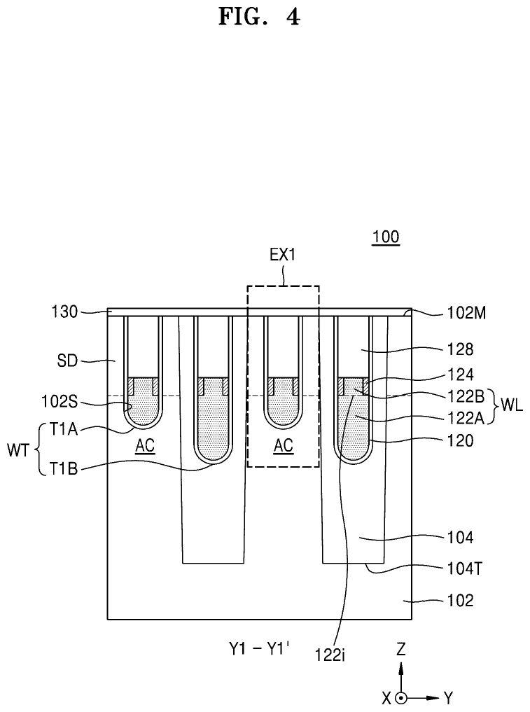

FIG. 4 is a cross-sectional view illustrating some elements of a cross-section taken along line Y1-Y1′ in FIG. 1B.

Referring to FIGS. 2 to 4, the integrated circuit device 100 may include a substrate 102 having an isolation trench 104T formed therein (e.g., a substrate 102 having one or more inner surfaces 102S defining the isolation trench 104T). The isolation trench 104T may be filled (e.g., partially or entirely) with an isolation film 104. A plurality of active regions AC may be defined in the substrate 102 by the isolation trench 104T and the isolation film 104.

The isolation film 104 may surround the active regions AC in the substrate 102. The isolation film 104 may include a silicon oxide film, a silicon nitride film, or any combination thereof. The vertical level of the bottom surface of the isolation trench 104T may vary with a horizontal width of the isolation trench 104T. When the horizontal width of the isolation trench 104T increases, the vertical level of the bottom surface of the isolation trench 104T may be further away from a main surface 102M of the substrate 102. The terms “level,” “vertical level,” or the like used herein may refer to a height from the main surface 102M of the substrate 102 in the vertical direction (the Z direction or the −Z direction). The vertical direction (the Z direction or the −Z direction) may extend perpendicular to the main surface 102M of the substrate 102 and/or may extend perpendicular to one or both of the first and second horizontal directions (the X and Y directions).

The substrate 102 may include silicon, for example, monocrystalline silicon, polycrystalline silicon, or amorphous silicon. In some example embodiments, the substrate 102 may include at least one selected from the group consisting of Ge, SiGe, SiC, GaAs, InAs, and InP. In some example embodiments, the substrate 102 may include a conductive region, e.g., a dopant-doped well or a dopant-doped structure.

A plurality of word line trenches WT may extend in the first horizontal direction (the X direction) in the substrate 102 and may be parallel with each other. The substrate 102 may include one or more inner surfaces 102S that define one or more word line trenches WT within a volume space defined by outermost surfaces (e.g., the main surface 102M) of the substrate 102. As a result the one or more word line trenches WT may be understood to be within the substrate 102, form within the substrate 102, or the like. Each of the word line trenches WT may have a line shape, which extends long in (e.g., extends longitudinally in) the first horizontal direction (the X direction) across the active regions AC and the isolation film 104. The inside of each of the word line trenches WT may be filled (e.g., partially or entirely filled) with a gate dielectric film 120, a word line WL, and an insulating capping pattern 128.

As shown in FIG. 2, the vertical level of the bottom surfaces of portions of each of the word line trenches WT, which are respectively on the active regions AC (e.g., on separate, respective active regions AC in the vertical direction (the Z direction), may be higher than the vertical level of the bottom surfaces of portions of each word line trench WT, which are on the isolation film 104. Accordingly, the bottom surface profile of the word line trench WT may have a concave-convex shape, and the bottom surface of the word line WL may also have a concave-convex shape in correspondence to (e.g., complementary to) the bottom surface profile (e.g., shape) of the word line trench WT. The active regions AC may respectively have fin areas AF (e.g., have separate, respective fin areas AF), which protrude upwards from a lower portion (e.g., a bottom surface) of the word line WL in the vertical direction (the Z direction) in correspondence to the bottom surface profile of the word line trench WT.

The plurality of word line trenches WT may include a first trench portion TIA, which is in the substrate 102 and has a bottommost surface at a first vertical level LV1, and a second trench portion T1B, which is in the isolation film 104 and has a bottommost surface at a second vertical level LV2 that is lower than the first vertical level LV1.

The gate dielectric film 120 may conformally cover (e.g., conformally directly contact) the inner surface of each of the word line trenches WT and may be in contact with the active regions AC and the isolation film 104. The inner surface(s) of the word line trenches WT may be defined by and/or may be the one or more inner surfaces 102S of the substrate 102 that define the word line trenches WT. The gate dielectric film 120 may include a silicon oxide film, e.g., an SiO₂ film. The gate dielectric film 120 may have a thickness of about 10 nm to about 30 nm but is not limited thereto.

Each of the word lines WL may extend long (e.g., extend longitudinally) on the gate dielectric film 120 in the first horizontal direction (the X direction) and fill (partially or entirely) a lower space of one of the word line trenches WT (e.g., a lowermost portion of the one of the word line trenches WT remaining after the gate dielectric film 120 conformally covers the inner surface of the one of the word line trenches WT). The insulating capping pattern 128 may extend long (e.g., extend longitudinally) on each of the word lines WL in the first horizontal direction (the X direction) and fill (partially or entirely) an upper space of the word line trench WT (e.g., an upper portion of the one of the word line trenches WT remaining after the gate dielectric film 120 conformally covers the inner surface of the one of the word line trenches WT and the word line WL fills the lower space of the word line trench WT), such that the word line WL may be between the insulating capping pattern 128 and an inner surface of the word line trench WT (which may be defined by an inner surface 102S) and/or the gate dielectric film 120 in the vertical direction (Z direction).

As shown in FIG. 4, each of the word lines WL may include a lower conductive plug 122A and an upper conductive plug 122B, which at least partially overlap each other in the vertical direction (the Z direction). A pair of ferroelectric layers 124 may be arranged at an upper portion (e.g., a top portion) of each word line WL, for example such that the pair of ferroelectric layers 124 may be between at least a portion of the word line WL and the insulating capping pattern 128 in the vertical direction (the Z direction). For example, a ferroelectric layer 124 may be arranged at an upper portion (e.g., a top portion) of a word line WL such that a top surface 124T of the ferroelectric layer 124 may be exposed from the top surface WLT of the word line WL in the vertical direction (Z direction) and/or may be coplanar with the top surface WLT of the word line WL, such that the top surface 124T of the ferroelectric layer 124 may be exposed to and/or in contact with a bottom surface 128B of the insulating capping pattern 128. In detail, the ferroelectric layers 124 may be respectively on opposite side surfaces of the upper conductive plug 122B. The ferroelectric layers 124 may be apart from each other in the second horizontal direction (the Y direction). The upper conductive plug 122B may be between the ferroelectric layers 124 in the second horizontal direction (the Y direction). In some example embodiments, the lower and upper conductive plugs 122A and 122B may be separate portions of a single, unitary piece of material, and the boundary 122i between the lower and upper conductive plugs 122A and 122B may be defined by a bottom surface 124B of the ferroelectric layers 124. In some example embodiments, the lower and upper conductive plugs 122A and 122B may be separate pieces of material, and the boundary 122i between the lower and upper conductive plugs 122A and 122B is defined by opposing surfaces of the lower and upper conductive plugs 122A and 122B, including the top surface 122AT of the lower conductive plug 122A which may contact both a bottom surface 124B of the ferroelectric layers 124 and a lower surface of the upper conductive plug 122B.

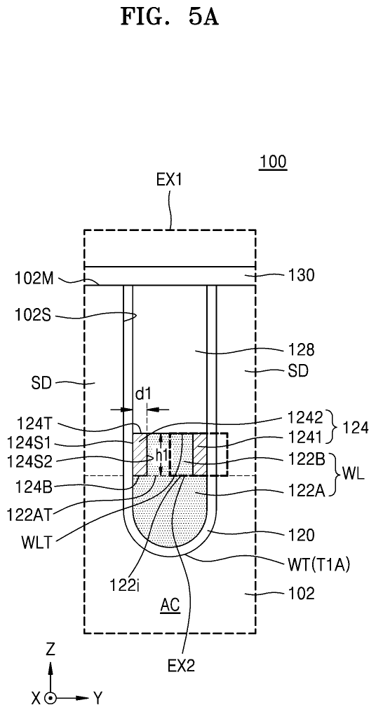

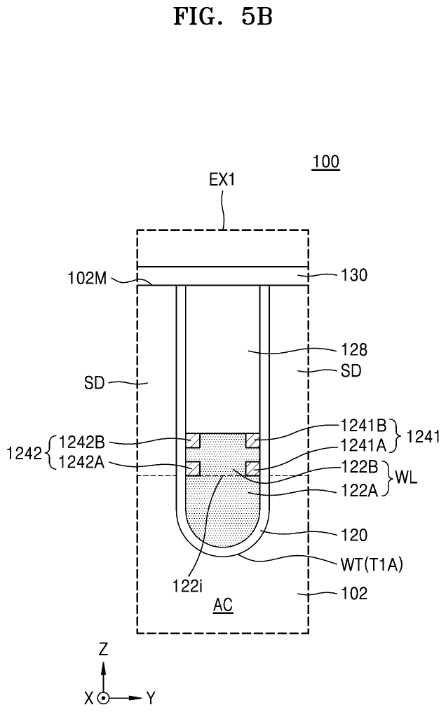

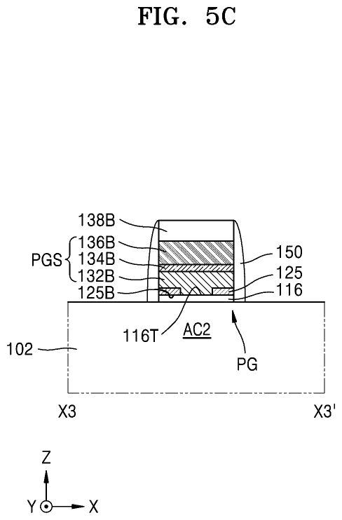

As shown in at least FIG. 5A, each of the ferroelectric layers 124 may include a first sidewall 124S1 and a second sidewall 124S2. In some example embodiments, among sidewalls of each ferroelectric layer 124 in the second horizontal direction (the Y direction), the first sidewall 124S1 of the ferroelectric layer 124 may be in contact with the gate dielectric film 120. Among the sidewalls of the ferroelectric layer 124 in the second horizontal direction (the Y direction), the second sidewall 124S2 of the ferroelectric layer 124 may be in contact with the upper conductive plug 122B. The first sidewall 124S1 and the second sidewall 124S2 of each of the ferroelectric layers 124 may face each other (e.g., may be opposite to each other, may face oppositely away from each other) in the second horizontal direction (the Y direction). In other words, the ferroelectric layer 124 may be between the gate dielectric film 120 and the upper conductive plug 122B (e.g., in the second horizontal direction, or Y direction). The ferroelectric layer 124 may be in contact with the gate dielectric film 120 and the upper conductive plug 122B and may extend long (e.g., have a longitudinal axis extending) in the first horizontal direction (the X direction).

The upper conductive plug 122B and the ferroelectric layer 124 may be between the lower conductive plug 122A and the insulating capping pattern 128 in the vertical direction (the Z direction). The top surface of the upper conductive plug 122B may be in contact with the bottom surface of the insulating capping pattern 128 and the bottom surface of the upper conductive plug 122B may be in contact with the top surface of the lower conductive plug 122A. The top surface 124T of the ferroelectric layer 124 may be in contact with the bottom surface 128B of the insulating capping pattern 128 and the bottom surface 124B of the ferroelectric layer 124 may be in contact with the top surface 122AT of the lower conductive plug 122A. In some example embodiments, for example in example embodiments where the lower and upper conductive plugs 122B are separate portions of a single, unitary piece of material, the bottom surface 124B (which may be a lowermost surface in the vertical direction) of the ferroelectric layer 124 may define a boundary 122i in at least the vertical direction (Z direction) between the lower conductive plug 122A and the upper conductive plug 122B, and the bottom surface 124B may be coplanar with a bottom surface of the upper conductive plug 122B. As shown, the top surface 124T of the ferroelectric layer 124 may be exposed from a top surface WLT of the word line WL (which may be defined by a top surface of the upper conductive plug 122B) in the vertical direction (Z direction) and/or may be coplanar or substantially coplanar with the top surface WLT of the word line WL. As a result, the ferroelectric layer 124 may be understood to be at a top portion of the word line WL.

In some example embodiments, the lower conductive plug 122A and the upper conductive plug 122B of the word line WL may include undoped conductive metal nitride. For example, the lower conductive plug 122A and the upper conductive plug 122B may include an undoped TiN plug. However, example embodiments are not limited thereto. The lower conductive plug 122A and the upper conductive plug 122B may include different materials from each other. In some example embodiments, the ferroelectric layer 124 may include hafnium zirconium oxide (HfZrO₂) but is not limited thereto.

The insulating capping pattern 128 may be on the word line WL and may fill the remaining space of the word line trench WT. In some example embodiments, the insulating capping pattern 128 may include a silicon nitride film, a silicon oxynitride film, a silicon oxide film, or any combination thereof. For example, the insulating capping pattern 128 may be constituted of a silicon nitride film. For example, the insulating capping pattern 128 may be constituted of a silicon oxide film, which covers the top surface of the upper conductive plug 122B and at least a portion of the surface of the gate dielectric film 120, and a silicon nitride film, which is on the silicon oxide film and fills an upper space of the word line trench WT.

In each of the active regions AC, a plurality of source/drain regions SD may be respectively at opposite sides of the word line WL. Each of the source/drain regions SD may include an impurity region, which includes impurity ions implanted into the substrate 102. The sidewall of the upper conductive plug 122B may face a pair of source/drain regions SD, which are respectively at opposite sides in the second horizontal direction (the Y direction), with the gate dielectric film 120 between the upper conductive plug 122B and the source/drain regions SD.

As shown in FIGS. 2 to 4, the main surface 102M of the substrate 102, the isolation film 104, and the insulating capping pattern 128 may be covered with a buffer insulating film 130. The buffer insulating film 130 may include an oxide film, a nitride film, or any combination thereof. As shown in FIG. 3, each of the direct contacts DC may be on a portion of one of the active regions AC. As shown in FIGS. 2 and 3, a plurality of bit lines BL may be on the buffer insulating film 130 and a plurality of direct contacts DC and may extend long in the second horizontal direction (the Y direction). The bit lines BL may be respectively covered with a plurality of first insulating capping patterns 138A.

A plurality of conductive plugs 140P and a plurality of insulating fences 142 may be alternately arranged in line between two adjacent bit lines BL among the bit lines BL. The insulating fences 142 may respectively fill a plurality of recesses 128R, which is in the top surface of the insulating capping pattern 128, and each of the insulating fences 142 may be between two adjacent conductive plugs 140P. The opposite sidewalls of each of the conductive plugs 140P in the second horizontal direction (the Y direction) may be respectively covered with insulating fences 142. The conductive plugs 140P arranged in line in the second horizontal direction (the Y direction) may be insulated from one another by the plurality of insulating fences 142. The conductive plugs 140P may respectively form the buried contacts BC in FIG. 1B.

Each of the bit lines BL may be connected to an active region AC through a direct contact DC. One direct contact DC and a pair of conductive plugs 140P, which face each other with the direct contact DC therebetween, may be respectively connected to active regions AC. In some example embodiments, the direct contact DC may include Si, Ge, W, WN, Co, Ni, Al, Mo, Ru, Ti, TiN, Ta, TaN, Cu, or any combination thereof. For example, the direct contact DC may include an epitaxial silicon layer.

Each of the bit lines BL may include a first lower conductive layer 132A, a first middle conductive layer 134A, and a first upper conductive layer 136A, which are sequentially formed above the substrate 102. The top surface of the first middle conductive layer 134A may be coplanar with the top surface of the direct contact DC. Although it is illustrated in FIGS. 2 and 3 that each of the bit lines BL has a triple-layer structure including the first lower conductive layer 132A, the first middle conductive layer 134A, and the first upper conductive layer 136A, the inventive concepts are not limited thereto. For example, each of the bit lines BL may have a single-layer structure or a stack structure of two layers or at least four layers.

In some example embodiments, the first lower conductive layer 132A may include conductive polysilicon. The first middle conductive layer 134A and the first upper conductive layer 136A may each include TIN, TiSiN, W, tungsten silicide, or any combination thereof. For example, the first middle conductive layer 134A may include TiN and/or TiSiN and the first upper conductive layer 136A may include W. The first insulating capping patterns 138A may include a silicon nitride film.

Each of the conductive plugs 140P may be on the substrate 102 and may have a pillar shape, which extends in the vertical direction (the Z direction) between two adjacent bit lines BL. The bottom surface of each of the conductive plugs 140P may be in contact with one of the active regions AC. A portion of each of the conductive plugs 140P may be at a lower level than the main surface 102M of the substrate 102. The conductive plugs 140P may include doped polysilicon, metal, conductive metal nitride, or any combination thereof.

Each of the insulating fences 142 may have a pillar shape, which extends in the vertical direction (the Z direction) between two adjacent bit lines BL. The insulating fences 142 may include a silicon nitride film.

The opposite sidewalls of each of the bit lines BL, the first insulating capping patterns 138A, and the direct contact DC may be respectively covered with insulating spacers 146. The insulating spacers 146 may be respectively on the opposite sidewalls of each bit line BL and may extend long (e.g., have a longitudinal axis extending) in the second horizontal direction (the Y direction) to be parallel with the bit line BL. The insulating spacers 146 may include an oxide film, a nitride film, an air spacer, or any combination thereof. The term “air” used herein may refer to the atmosphere or other gases that may exist in manufacturing processes.

Each of the conductive plugs 140P may be separated from (e.g., spaced apart from) one of the bit lines BL by one of the insulating spacers 146 in the first horizontal direction (the X direction). Each of the insulating fences 142 may be separated from a bit line BL by an insulating spacer 146 in the first horizontal direction (the X direction).

A metal silicide film 172 and a conductive landing pad LP may be sequentially formed on each of the conductive plugs 140P. The metal silicide film 172 and the conductive landing pad LP may vertically overlap each of the conductive plugs 140P. The metal silicide film 172 may be between the conductive landing pad LP and each of the conductive plugs 140P and separated from the bit line BL by the insulating spacer 146. The metal silicide film 172 may include cobalt silicide, nickel silicide, or manganese silicide.

The conductive landing pad LP may be connected to each of the conductive plugs 140P through the metal silicide film 172. The conductive landing pad LP may extend from a space between adjacent first insulating capping patterns 138A to a space above one of the first insulating capping patterns 138A so as to vertically overlap a portion of the bit line BL. The conductive landing pad LP may include a conductive barrier film 174 and a conductive layer 176. The conductive barrier film 174 may include Ti, TiN, or any combination thereof. The conductive layer 176 may include metal, metal nitride, conductive polysilicon, or any combination thereof. For example, the conductive layer 176 may include tungsten (W).

According to a plan view, the plurality of conductive landing pads LP may have island patterns. The conductive landing pads LP may be electrically insulated from each other by an insulating film 180, which fills an insulating space 180S around the conductive landing pads LP. The insulating film 180 may include a silicon nitride film, a silicon oxide film, or any combination thereof.

According to some example embodiments, when the integrated circuit device 100 includes a pair of ferroelectric layers 124 partially arranged at an upper portion of each of the word lines WL, the characteristics of the integrated circuit device 100 may be improved. Due to the polarization of the pair of ferroelectric layers 124, an electric field may be formed from each of the word lines WL toward the gate dielectric film 120. When the electric field is formed in one direction by the polarization of the pair of ferroelectric layers 124, the turn-on current of a transistor may increase, and accordingly, the electrical characteristics of the integrated circuit device 100 may be improved. The leakage current of the integrated circuit device 100 may be reduced by forming an electric field in one direction by using the polarization of the pair of ferroelectric layers 124, and accordingly, the electrical characteristics of the integrated circuit device 100 may be improved. As a result, the functionality of the integrated circuit device 100 and any electronic device including same may be improved, such improved functionality including, for example, improved performance (e.g., improved refresh functionality, reduced drain leakage without compromising last data into row free charge time (tRDL), etc.), reduced power consumption by the integrated circuit device 100 without compromising performance of the integrated circuit device 100 (e.g., based on the reduced drain leakage), any combination thereof, or the like.

FIGS. 5A and 5B are enlarged cross-sectional views of a region EX1 in FIG. 4.

Referring to FIG. 5A, the pair of ferroelectric layers 124 may include a first ferroelectric layer 1241 and a second ferroelectric layer 1242. The first ferroelectric layer 1241 and the second ferroelectric layer 1242 may face each other and may be spaced apart from each other by a certain distance in the second horizontal direction (the Y direction). The upper conductive plug 122B, and thus at least a portion of the word line WL, may be between the first ferroelectric layer 1241 and the second ferroelectric layer 1242 (e.g., in the second horizontal direction (the Y direction)). As shown in FIG. 5A, the first ferroelectric layer 1241 and the second ferroelectric layer 1242 may each include a first sidewall 124S1 that may be in contact with the gate dielectric film 120 and a second sidewall 124S2 that may be in contact with the upper conductive plug 122B.

Each of the first ferroelectric layer 1241 and the second ferroelectric layer 1242 may have a thickness dl (e.g., a thickness in the second horizontal direction (the Y direction)). For example, the thickness dl of each of the first ferroelectric layer 1241 and the second ferroelectric layer 1242 may be less than 2 nm.

As shown in FIG. 5A, the first ferroelectric layer 1241 and the second ferroelectric layer 1242 may have the same thickness dl (e.g., thickness in the second horizontal direction, or Y direction) and height h1 (e.g., thickness in the vertical direction, or Z direction), but the inventive concepts are not limited thereto. For example, the thickness dl (e.g., width) of the first ferroelectric layer 1241 may be different from the thickness dl (e.g., width) of the second ferroelectric layer 1242. The height h1 of the first ferroelectric layer 1241 may be different from the height h1 of the second ferroelectric layer 1242. For example, the thickness dl and the height h1 of the first ferroelectric layer 1241 may be greater than the thickness dl and the height h1 of the second ferroelectric layer 1242.

In some example embodiments, instead of the pair of ferroelectric layers 124, a single ferroelectric layer 124 may be provided. For example, the first ferroelectric layer 1241 may be arranged on a side surface of the upper conductive plug 122B. For example, the second ferroelectric layer 1242 may be arranged on a side surface of the upper conductive plug 122B. The shape (thickness and/or height) and number of ferroelectric layers 124 arranged on a side surface of the upper conductive plug 122B may be variously adjusted when necessary.

Referring to FIG. 5B, according to some example embodiments, there may be a plurality of first ferroelectric layers 1241 and second ferroelectric layers 1242. For example, the first ferroelectric layers 1241 may include a first lower ferroelectric layer 1241A and a first upper ferroelectric layer 1241B. The first lower ferroelectric layer 1241A and the first upper ferroelectric layer 1241B may be apart (e.g., spaced apart) from each other in the vertical direction (the Z direction). The upper conductive plug 122B (e.g., at least a portion thereof) may be between, and thus may vertically overlap, the first lower ferroelectric layer 1241A and the first upper ferroelectric layer 1241B.

The second ferroelectric layers 1242 may include a second lower ferroelectric layer 1242A and a second upper ferroelectric layer 1242B. The second lower ferroelectric layer 1242A and the second upper ferroelectric layer 1242B may be apart (e.g., spaced apart) from each other in the vertical direction (the Z direction). The upper conductive plug 122B (e.g., at least a portion thereof) may be between, and thus may vertically overlap, the second lower ferroelectric layer 1242A and the second upper ferroelectric layer 1242B.

As shown in FIG. 5B, the top and bottom surfaces of each of the first lower ferroelectric layer 1241A and the second lower ferroelectric layer 1242A may be in contact with a word line WL. As shown in FIG. 5B, the respective top surfaces of the first upper ferroelectric layer 1241B and the second upper ferroelectric layer 1242B may be in contact with the insulating capping pattern 128. As shown in FIG. 5B, the respective bottom surfaces of the first upper ferroelectric layer 1241B and the second upper ferroelectric layer 1242B may be in contact with the word line WL (e.g., at least a portion of the upper conductive plug 122B).

Although there are two first ferroelectric layers 1241 and two second ferroelectric layers 1242 in FIG. 5B, the inventive concepts are not limited thereto. For example, there may be at least three first ferroelectric layers 1241 and at least three second ferroelectric layers 1242.

FIG. 5C is an enlarged cross-sectional view illustrating some elements of a cross-section taken along line X3-X3′ in FIG. 1B.

FIG. 5C is an enlarged cross-sectional view taken along line X3-X3′ in FIG. 1B. FIG. 5C is an enlarged cross-sectional view of the peripheral circuit transistor PG in the peripheral circuit region PCA. The peripheral circuit transistor PG may be arranged on a second active region AC2 in the peripheral circuit region PCA. The second active region AC2 may be defined in the substrate 102 by the isolation film 104 (see FIG. 3) in the peripheral circuit region PCA. The peripheral circuit transistor PG may include a peripheral circuit gate dielectric film 116, a peripheral circuit gate electrode PGS, and a gate capping pattern 138B, which are sequentially stacked on the second active region AC2. The peripheral circuit region PCA may include a plurality of second active regions AC2 defined by the isolation film 104 and may include a peripheral circuit transistor PG on each of the plurality of second active regions AC2.

The peripheral circuit gate dielectric film 116 may include at least one selected from the group consisting of a silicon oxide film, a silicon nitride film, a silicon oxynitride film, oxide/nitride/oxide (ONO), and a high-k dielectric film having a higher dielectric constant than the silicon oxide film. The peripheral circuit gate electrode PGS may include a second lower conductive layer 132B, a second middle conductive layer 134B, and a second upper conductive layer 136B. The materials of the second lower conductive layer 132B, the second middle conductive layer 134B, and the second upper conductive layer 136B may be respectively the same as the materials of the first lower conductive layer 132A, the first middle conductive layer 134A, and the first upper conductive layer 136A of each of the bit lines BL in the cell array region MCA. The gate capping pattern 138B may include a silicon nitride film. Each of the opposite sidewalls of the peripheral circuit gate electrode PGS may be covered with an insulating spacer 150. The insulating spacer 150 may include an oxide film, a nitride film, or any combination thereof.

A pair of peripheral circuit ferroelectric layers 125 may be arranged at a lower portion of the peripheral circuit gate electrode PGS, for example being below the peripheral circuit gate electrode PGS in the vertical direction (Z direction), such that the pair of peripheral circuit ferroelectric layers 125 may be between (e.g., at least partially vertically overlapping) at least a portion of the peripheral circuit gate electrode PGS and the peripheral circuit gate dielectric film 116 in the vertical direction (Z direction). In detail, the pair of peripheral circuit ferroelectric layers 125 may be below the second lower conductive layer 132B, for example such that the pair of peripheral circuit ferroelectric layers 125 may be between (e.g., at least partially vertically overlapping) at least a portion of the second lower conductive layer 132B and the peripheral circuit gate dielectric film 116 in the vertical direction (Z direction). The peripheral circuit ferroelectric layers 125 may be apart (e.g., spaced apart) from each other (e.g., spaced apart by a certain distance) in the first horizontal direction (the X direction). The second lower conductive layer 132B may be between the peripheral circuit ferroelectric layers 125 in the first horizontal direction (the X direction).

As shown in at least FIG. 5C, the bottom surface 125B of each of the peripheral circuit ferroelectric layers 125 may be in contact with the top surface 116T of the peripheral circuit gate dielectric film 116. A side surface of each of the peripheral circuit ferroelectric layers 125 may be in contact with a side surface of the insulating spacer 150. Each of the peripheral circuit ferroelectric layers 125 may be in contact with the peripheral circuit gate dielectric film 116 and the insulating spacer 150 and may extend long in the second horizontal direction (the Y direction). At this time, the peripheral circuit ferroelectric layers 125 may include hafnium zirconium oxide (HfZrO₂) but are not limited thereto.

When a high voltage Vpp is applied to the peripheral circuit gate electrode PGS, each of the peripheral circuit ferroelectric layers 125 may be polarized such that the dipole of each peripheral circuit ferroelectric layer 125 has positive charges near the peripheral circuit gate dielectric film 116 and negative charges near the second lower conductive layer 132B.

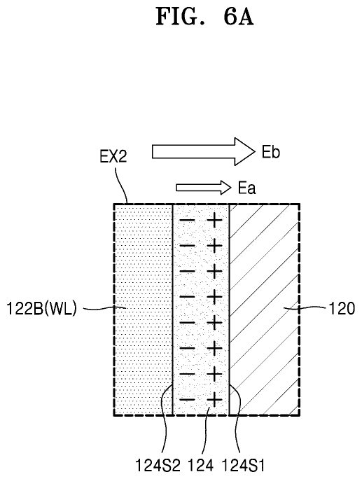

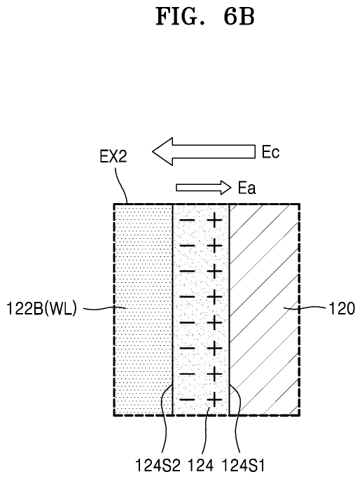

Due to the polarization of the peripheral circuit ferroelectric layers 125, an electric field may be formed from the second lower conductive layer 132B toward the peripheral circuit gate dielectric film 116. When the electric field is formed in one direction by the polarization of the pair of peripheral circuit ferroelectric layers 125, the turn-on current of a transistor may increase, and accordingly, the electrical characteristics of the integrated circuit device 100 may be improved. The leakage current of the integrated circuit device 100 may be reduced by forming an electric field in one direction by using the polarization of the pair of peripheral circuit ferroelectric layers 125. As a result, the functionality of the integrated circuit device 100 and any electronic device including same may be improved, such improved functionality including, for example, improved performance (e.g., improved turn-on current, reduced leakage current, etc.), reduced power consumption by the integrated circuit device 100 without compromising performance of the integrated circuit device 100 (e.g., based on the reduced leakage current), any combination thereof, or the like. The effects of an electric field formed by polarization are described in detail below. The effects of the pair of peripheral circuit ferroelectric layers 125 may be the same as that described below with reference to FIGS. 6A and 6B.

FIGS. 6A and 6B are enlarged cross-sectional views of a region EX2 in FIG. 5A. The effects of an integrated circuit device of the inventive concepts are described below with reference to FIGS. 6A and 6B.

Referring to FIG. 6A, when a high voltage is applied to the word line WL (see FIG. 5A) of the integrated circuit device 100, a transistor may be turned on and a first electric field Eb may be formed. At this time, the high voltage may be 3 V but is not limited thereto. The first electric field Eb may be formed in a direction from the upper conductive plug 122B to the gate dielectric film 120.

The ferroelectric layer 124 may be polarized due to the high voltage applied to the word line WL such that the dipole of the ferroelectric layer 124 has positive charges near the gate dielectric film 120 and negative charges near the upper conductive plug 122B.

In some example embodiments, an electric field Ea may be formed by the polarization of the ferroelectric layer 124. The electric field Ea generated by the ferroelectric layer 124 may be a fixed electric field and formed in a direction from the upper conductive plug 122B to the gate dielectric film 120. The strength of the electric field Ea generated by the ferroelectric layer 124 may vary with the thickness (dl in FIG. 5A) of the ferroelectric layer 124. At this time, the strength of the electric field Ea generated by the ferroelectric layer 124 may be 0.05 V/1 nm but is not limited thereto. For example, when the thickness of the ferroelectric layer 124 is less than 2 nm, the strength of the electric field Ea generated by the ferroelectric layer 124 may be less than 0.1 V.

When the transistor is turned on, the first electric field Eb and the electric field Ea generated by the ferroelectric layer 124 may be formed in the same direction. Due to the first electric field Eb and the electric field Ea generated by the ferroelectric layer 124, the resistance of a buried contact region connected to a source/drain region (SD in FIG. 5A) may decrease. As the resistance of the buried contact region decreases, the turn-on current of the transistor may increase. As the resistance of the buried contact region decreases, a last data into row free charge time (tRDL) may be improved. As the turn-on current of the transistor increases, the characteristics of data write operation and refresh operation may be improved, and accordingly, the electrical characteristics of the integrated circuit device 100 may also be improved. As a result, the functionality of the integrated circuit device 100 and any electronic device including same may be improved based on including one or more ferroelectric layers 124, such improved functionality including, for example, improved performance (e.g., improved data write operation and refresh operation performance).

Referring to FIG. 6B, when a negative voltage VBB2 is applied to the word line WL (see FIG. 5A) of the integrated circuit device 100, a transistor may be turned off and a second electric field Ec may be formed. At this time, the negative voltage may be −0.8 V but is not limited thereto. The second electric field Ec may be formed in a direction from the gate dielectric film 120 to the upper conductive plug 122B.

When the transistor is turned on, the ferroelectric layer 124 may be polarized due to the high voltage applied to the word line WL such that the dipole of the ferroelectric layer 124 has positive charges near the gate dielectric film 120 and negative charges near the upper conductive plug 122B.

In some example embodiments, the electric field Ea may be formed by the polarization of the ferroelectric layer 124. The electric field Ea generated by the ferroelectric layer 124 may be a fixed electric field and formed in a direction from the upper conductive plug 122B to the gate dielectric film 120. The strength of the electric field Ea generated by the ferroelectric layer 124 may vary with the thickness (dl in FIG. 5A) of the ferroelectric layer 124. At this time, the strength of the electric field Ea generated by the ferroelectric layer 124 may be 0.05 V/1 nm but is not limited thereto. For example, when the thickness of the ferroelectric layer 124 is less than 2 nm, the strength of the electric field Ea generated by the ferroelectric layer 124 may be less than 0.1 V.

When the transistor is turned off, the second electric field Ec and the electric field Ea generated by the ferroelectric layer 124 may be formed in opposite directions. Because the direction of the electric field Ea generated by the ferroelectric layer 124 is opposite to the direction of the second electric field Ec, there is an effect of decreasing gate induced drain leakage (GIDL). Because the strength of the second electric field Ec is weakened by the strength of the electric field Ea generated by the ferroelectric layer 124, leakage current may be decreased. As the leakage current of the integrated circuit device 100 is decreased, a data retention time may be prevented from decreasing, and accordingly, refresh characteristics may be improved. As a result, the functionality of the integrated circuit device 100 and any electronic device including same may be improved based on including one or more ferroelectric layers 124, such improved functionality including, for example, improved performance (e.g., improved data write operation and refresh operation performance), reduced power consumption by the integrated circuit device 100 without compromising performance of the integrated circuit device 100 (e.g., based on the reduced drain leakage) without compromising performance (e.g., data write operation and refresh operation performance) of the integrated circuit device 100 or any electronic device including same, any combination thereof, or the like.

In addition, the negative voltage may be increased by the strength of the electric field Ea generated by the ferroelectric layer 124. For example, when the strength of the electric field Ea generated by the ferroelectric layer 124 is 0.1 V, the negative voltage may be designed to be −0.9 V instead of −0.8 V. When the negative voltage may be designed to be −0.9 V, the characteristics of the transistor may be improved. Compared to when the negative voltage is designed to be −0.8 V, the passing gate effect (PGE) of the transistor may be improved when the negative voltage is designed to be −0.9 V. Compared to when the negative voltage is designed to be −0.8 V, the row disturb of the transistor may be improved when the negative voltage is designed to be −0.9 V.

The integrated circuit device 100 of the inventive concepts may include the ferroelectric layer 124 that is partially arranged, thereby increasing turn-on current when a transistor is turned on and decreasing leakage current when the transistor is turned off. As a result, the functionality (e.g., performance and/or power consumption efficiency) of the integrated circuit device 100 and any electronic device including same may be improved based on including one or more ferroelectric layers 124.

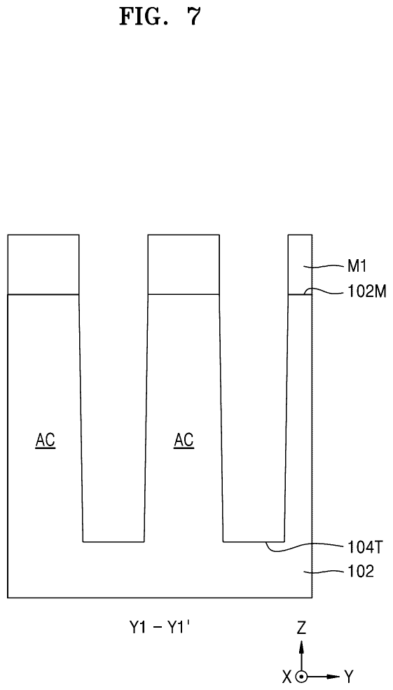

FIGS. 7, 8, 9, 10, 11, 12, 13, 14, and 15 are cross-sectional views of sequential stages in a method of manufacturing an integrated circuit device, according to embodiments, and correspond to the cross-section taken along line Y1-Y1′ in FIG. 1B.

Referring to FIG. 7, a mask pattern M1 may be formed on the main surface 102M of the substrate 102. An isolation trench 104T may be formed in the substrate 102 by etching the substrate 102 by using the mask pattern M1 as an etch mask. A plurality of active regions AC may be defined in the substrate 102 by the isolation trench 104T. The mask pattern M1 may be constituted of a hardmask including an oxide film, polysilicon, or any combination thereof.

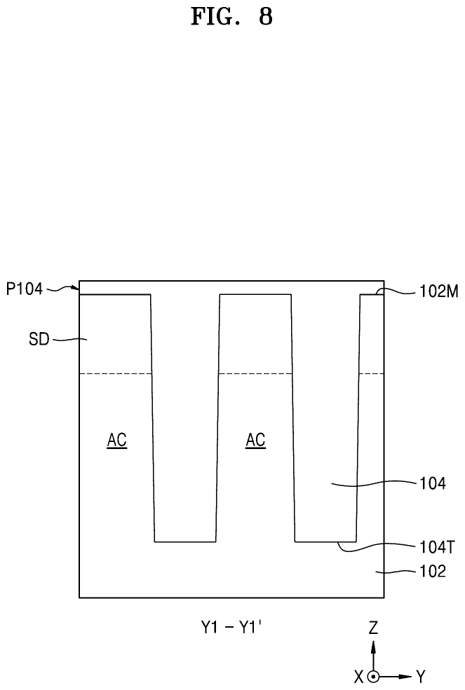

Referring to FIG. 8, after the mask pattern M1 is removed from the resultant structure of FIG. 7, an insulating film P104 may be formed to fill the isolation trench 104T and cover the main surface 102M of the substrate 102. Thereafter, ion-implantation may be performed to form a plurality of source/drain regions SD in the substrate 102. A portion of the insulating film P104 that fills the isolation trench 104T may become an isolation film 104. A portion of the insulating film P104 that covers the main surface 102M of the substrate 102 may protect the main surface 102M of the substrate 102 during ion-implantation to be performed to form the source/drain regions SD or a subsequent etching process.

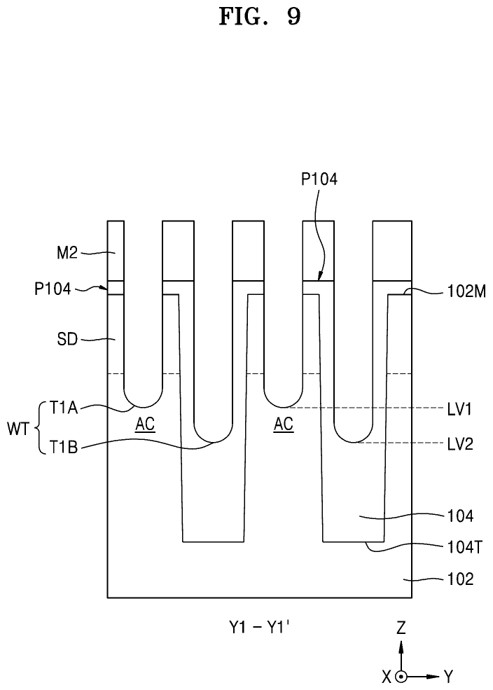

Referring to FIG. 9, a mask pattern M2 may be formed on the resultant structure of FIG. 8, and a plurality of word line trenches WT may be formed by etching a portion of the insulating film P104 and a portion of the substrate 102 by using the mask pattern M2 as an etch mask, wherein the word line trenches WT extend long (e.g., have a longitudinal axis extending) in the first horizontal direction (the X direction) across the active regions AC and the isolation film 104. Each of the word line trenches WT may include a first trench portion TIA, which has a bottom surface exposing the substrate 102 at a first vertical level LV1, and a second trench portion T1B, which has a bottom surface exposing the isolation film 104 at a second vertical level LV2 that is lower than the first vertical level LV1. The mask pattern M2 may include an oxide film, an amorphous carbon layer (ACL), an SiON film, or any combination thereof.

To form the word line trenches WT, a first etching process and a second etching process may be sequentially performed, wherein the substrate 102 and the isolation film 104 are etched from the main surface 102M of the substrate 102 at the same rate or substantially the same etch rate in the first etching process and the isolation film 104 is etched at a greater etch rate than the substrate 102 is etched in the second etching process. As a result, the second vertical level LV2 of the bottom surface of the second trench portion T1B exposing the isolation film 104 may be lower than the first vertical level LV1 of the bottom surface of the first trench portion TIA exposing the substrate 102. The first trench portion TIA and the second trench portion T1B may have substantially the same or similar widths in the second horizontal direction (the Y direction).

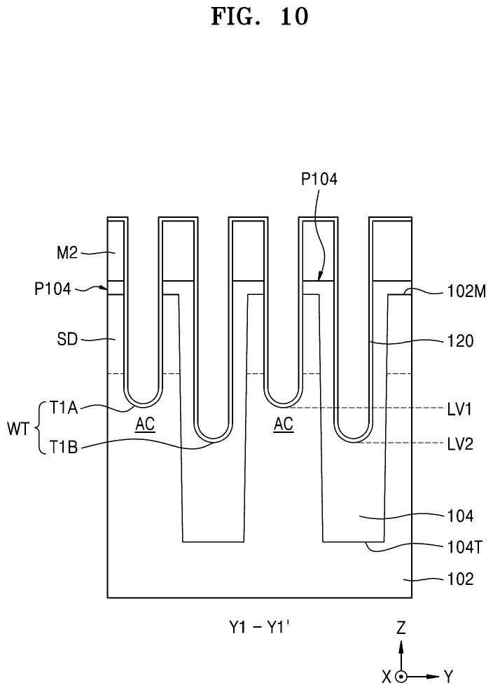

Referring to FIG. 10, a gate dielectric film 120 may be formed on the resultant structure of FIG. 9. The gate dielectric film 120 may be formed to conformally cover the inner wall of each of the word line trenches WT. The gate dielectric film 120 may include a silicon oxide film.

The gate dielectric film 120 may be formed by using atomic layer deposition (ALD). In some example embodiments, the process of forming the gate dielectric film 120 may be performed using an O₂ gas and an inert gas in a plasma atmosphere. In some example embodiments, the process of forming the gate dielectric film 120 may be performed using an O₂ gas, an inert gas, and an H₂ gas in a plasma atmosphere. In some example embodiments, during the process of forming the gate dielectric film 120, in-situ steam generation (ISSG) may be performed using vapor or a combination of an H₂ gas and an O₂ gas.

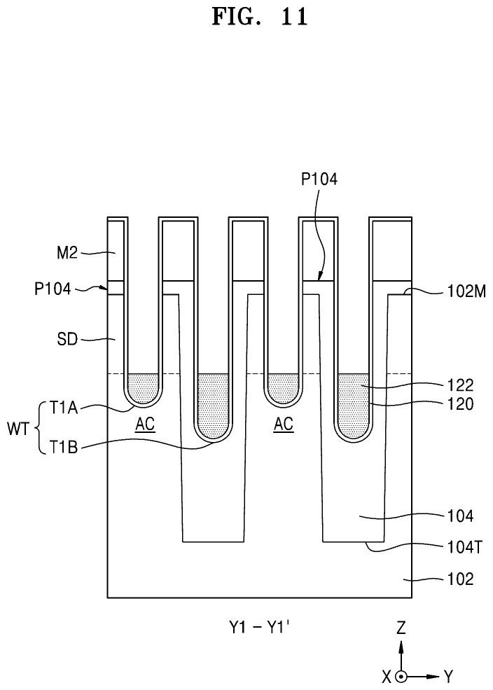

Referring to FIG. 11, a conductive metal nitride film 122 may be formed on the gate dielectric film 120 to fill a lower space of each of the word line trenches WT. The conductive metal nitride film 122 may include TiN.

In some example embodiments, to form the conductive metal nitride film 122, conductive metal nitride may be vapor-deposited to a thickness enough to fill each of the word line trenches WT and then partially etched back so that the conductive metal nitride film 122 remains in the lower space of each of the word line trenches WT. After the conductive metal nitride film 122 is formed, the upper space of each of the word line trenches WT may be empty.

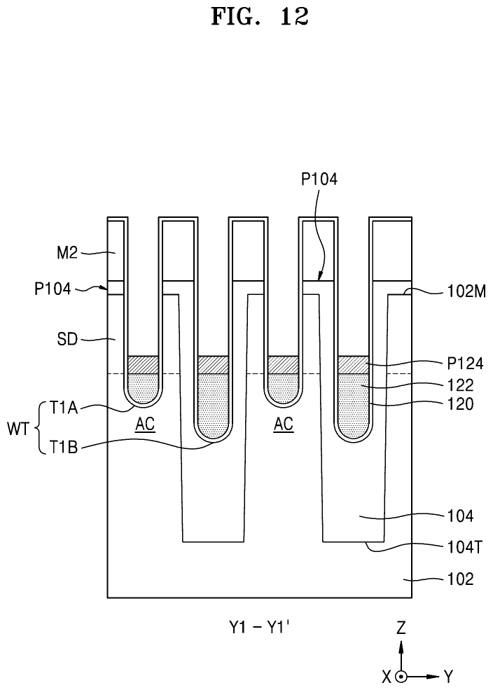

Referring to FIG. 12, a ferroelectric pattern P124 may be formed on the conductive metal nitride film 122 in each of the word line trenches WT. The ferroelectric pattern P124 may be formed to conformally cover the top surface of the conductive metal nitride film 122. At this time, the ferroelectric pattern P124 may include hafnium zirconium oxide (HfZrO₂) but is not limited thereto.

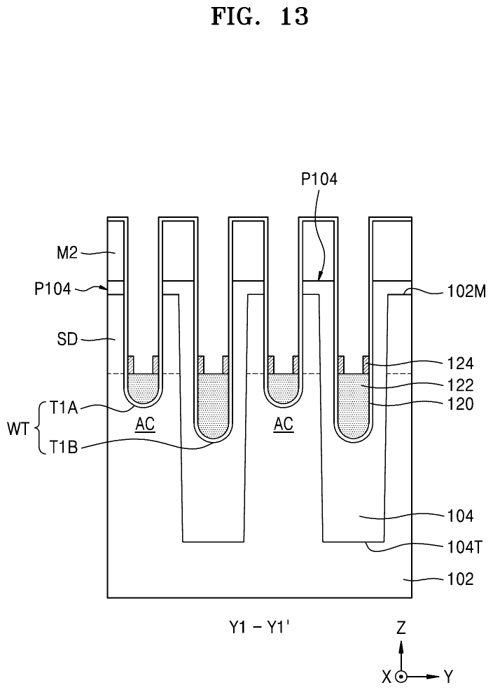

Referring to FIG. 13, a mask pattern (not shown) may be formed on the ferroelectric pattern P124 (see FIG. 12), and the ferroelectric pattern P124 may be partially etched by using the mask pattern as an etch mask. A pair of ferroelectric layers 124 may be formed by partially etching the ferroelectric pattern P124. A side surface of each of the ferroelectric layers 124 may be in contact with the gate dielectric film 120. The bottom surface of each of the ferroelectric layers 124 may be in contact with the top surface of the conductive metal nitride film 122. A certain space may be formed between the ferroelectric layers 124 in the second horizontal direction (the Y direction).

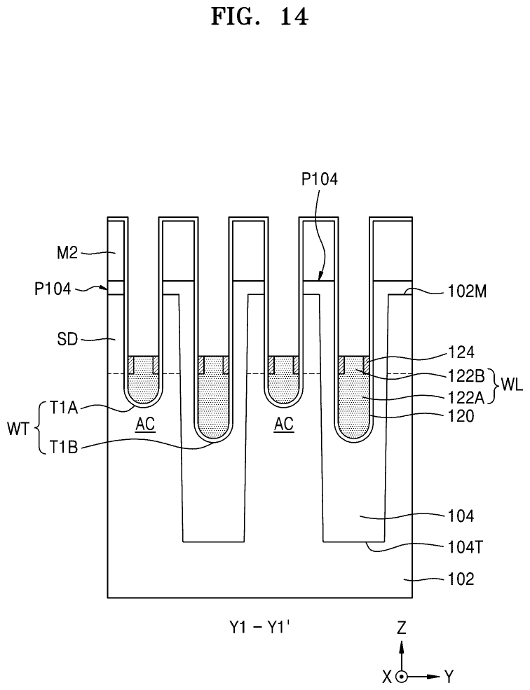

Referring to FIG. 14, a conductive metal nitride film 122 may be formed between the ferroelectric layers 124. Here, the conductive metal nitride film 122 between the ferroelectric layers 124 may be referred to as the upper conductive plug 122B, and the conductive metal nitride film 122 below the ferroelectric layers 124 may be referred to as the lower conductive plug 122A.

To form the upper conductive plug 122B, the conductive metal nitride film 122 may be vapor-deposited on the side and top surfaces of the ferroelectric layers 124 and then etched back. The conductive metal nitride film 122 may be etched back such that the top surface of the ferroelectric layers 124 is coplanar with the top surface of the upper conductive plug 122B.

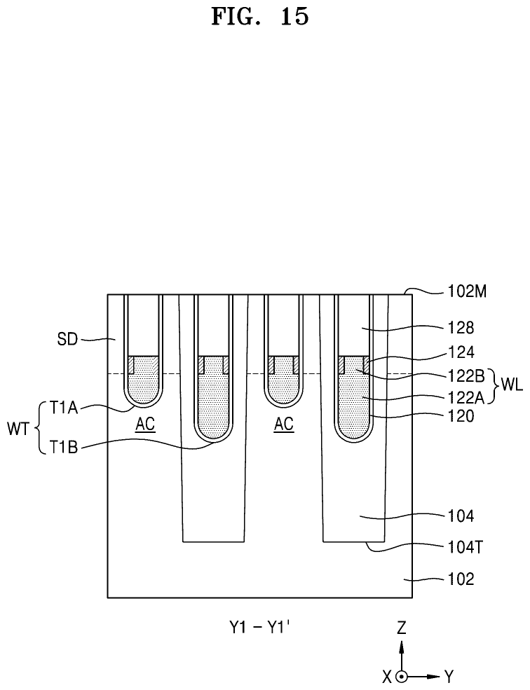

Referring to FIG. 15, an insulating capping pattern 128 may be formed to fill the upper space of each of the word line trenches WT in the resultant structure of FIG. 14. Thereafter, the main surface 102M of the substrate 102 may be exposed by removing unnecessary films from the substrate 102. In some example embodiments, to form the insulating capping pattern 128, the upper space of each of the word line trenches WT may be filled with a silicon nitride film.

The method of manufacturing the integrated circuit device 100 of FIGS. 1A and 1B has been described above with reference to FIGS. 7 to 15, but the inventive concepts are not limited thereto. Those skilled in the art will be well aware that integrated circuit devices variously changed and modified from the integrated circuit device 100 of FIGS. 1A and 1B may be manufactured by making various changes and modifications within the scope of the technical spirit of the inventive concepts.

While the inventive concepts have been particularly shown and described with reference to some example embodiments thereof, it will be understood that various changes in form and details may be made therein without departing from the spirit and scope of the following claims.

What is claimed is:

1. An integrated circuit device, comprising:
a substrate having formed therein a word line trench, the word line trench extending longitudinally in a first horizontal direction, the first horizontal direction extending parallel to a main surface of the substrate;
a gate dielectric film covering an inner surface of the word line trench;
a word line on the gate dielectric film, the word line filling a lower space of the word line trench and extending longitudinally in the first horizontal direction;
an insulating capping pattern on the word line, the insulating capping pattern filling an upper space of the word line trench and extending longitudinally in the first horizontal direction; and
at least one ferroelectric layer at a top portion of the word line, the at least one ferroelectric layer including a first sidewall in contact with the gate dielectric film.

2. The integrated circuit device of claim 1, wherein
the word line includes a lower conductive plug and an upper conductive plug on the lower conductive plug, and
the at least one ferroelectric layer further includes a second sidewall opposite to the first sidewall in a second horizontal direction, the second sidewall in contact with the upper conductive plug, the second horizontal direction extending parallel to the main surface of the substrate and perpendicular to the first horizontal direction.

3. The integrated circuit device of claim 2, wherein
a top surface of the at least one ferroelectric layer is in contact with a bottom surface of the insulating capping pattern, and
a bottom surface of the at least one ferroelectric layer is in contact with a top surface of the lower conductive plug.

4. The integrated circuit device of claim 1, wherein
the at least one ferroelectric layer includes a first ferroelectric layer and a second ferroelectric layer spaced apart from the first ferroelectric layer by a certain distance in a second horizontal direction, and
the first sidewall of each of the first ferroelectric layer and the second ferroelectric layer is in contact with the gate dielectric film.

5. The integrated circuit device of claim 4, wherein
the first ferroelectric layer faces the second ferroelectric layer, and
the word line is between the first ferroelectric layer and the second ferroelectric layer.

6. The integrated circuit device of claim 4, wherein a width of the first ferroelectric layer is different from a width of the second ferroelectric layer.

7. The integrated circuit device of claim 4, wherein a height of the first ferroelectric layer is different from a height of the second ferroelectric layer.

8. The integrated circuit device of claim 4, wherein
the first ferroelectric layer includes a first lower ferroelectric layer and a first upper ferroelectric layer spaced apart from the first lower ferroelectric layer in a vertical direction, the vertical direction extending perpendicular to the main surface of the substrate, and
the second ferroelectric layer includes a second lower ferroelectric layer and a second upper ferroelectric layer spaced apart from the second lower ferroelectric layer in the vertical direction.

9. The integrated circuit device of claim 8, wherein
top and bottom surfaces of each of the first lower ferroelectric layer and the second lower ferroelectric layer are in contact with the word line,
a top surface of each of the first upper ferroelectric layer and the second upper ferroelectric layer is in contact with the insulating capping pattern, and
a bottom surface of each of the first upper ferroelectric layer and the second upper ferroelectric layer is in contact with the word line.

10. The integrated circuit device of claim 1, wherein the at least one ferroelectric layer includes hafnium zirconium oxide (HfZrO₂).

11. An integrated circuit device, comprising:
a substrate including a cell array region and a peripheral circuit region;
a plurality of active regions defined by an isolation film, the plurality of active regions including a plurality of first active regions in the cell array region and a plurality of second active regions in the peripheral circuit region;
a word line trench extending longitudinally in a first horizontal direction across the plurality of first active regions, the first horizontal direction extending parallel to a main surface of the substrate;
a gate dielectric film covering an inner surface of the word line trench;
a word line on the gate dielectric film, the word line filling a lower space of the word line trench and extending longitudinally in the first horizontal direction;
an insulating capping pattern on the word line, the insulating capping pattern filling an upper space of the word line trench and extending longitudinally in the first horizontal direction; and
at least one ferroelectric layer at a top portion of the word line, the at least one ferroelectric layer including a first sidewall in contact with the gate dielectric film.

12. The integrated circuit device of claim 11, further comprising:
a peripheral circuit transistor on each of the plurality of second active regions,
wherein the peripheral circuit transistor includes a peripheral circuit gate dielectric film, a peripheral circuit gate electrode, and a gate capping pattern sequentially stacked on the each of the plurality of second active regions, and
at least one peripheral circuit ferroelectric layer is below the peripheral circuit gate electrode.

13. The integrated circuit device of claim 12, wherein
the peripheral circuit gate electrode includes a lower conductive layer, a middle conductive layer, and an upper conductive layer, and
the at least one peripheral circuit ferroelectric layer is below the lower conductive layer.

14. The integrated circuit device of claim 12, wherein a bottom surface of the at least one peripheral circuit ferroelectric layer is in contact with a top surface of the peripheral circuit gate dielectric film.

15. The integrated circuit device of claim 12, wherein the at least one ferroelectric layer and the at least one peripheral circuit ferroelectric layer includes hafnium zirconium oxide (HfZrO₂).

16. The integrated circuit device of claim 12, wherein the at least one peripheral circuit ferroelectric layer includes a plurality of peripheral circuit ferroelectric layers spaced apart from each other by a certain distance in the first horizontal direction.

17. The integrated circuit device of claim 11, wherein
the at least one ferroelectric layer further includes a second sidewall opposite to the first sidewall in a second horizontal direction and being in contact with the word line, the second horizontal direction extending parallel to the main surface of the substrate and perpendicular to the first horizontal direction, and
a bottom surface of the at least one ferroelectric layer is in contact with the word line.

18. An integrated circuit device, comprising:
a substrate having formed therein a word line trench, the word line trench extending longitudinally in a first horizontal direction, the first horizontal direction extending parallel to a main surface of the substrate;
a gate dielectric film covering an inner surface of the word line trench;
a word line on the gate dielectric film, the word line filling a lower space of the word line trench, the word line extending longitudinally in the first horizontal direction, the word line including a lower conductive plug and an upper conductive plug on the lower conductive plug;
an insulating capping pattern on the upper conductive plug, the insulating capping pattern filling an upper space of the word line trench and extending longitudinally in the first horizontal direction; and
a ferroelectric layer between the upper conductive plug and the gate dielectric film,
wherein the ferroelectric layer includes a first ferroelectric layer and a second ferroelectric layer spaced apart from the first ferroelectric layer by a certain distance in a second horizontal direction, the second horizontal direction extending parallel to the main surface of the substrate and perpendicular to the first horizontal direction,
each of the first ferroelectric layer and the second ferroelectric layer includes a first sidewall and a second sidewall, the first sidewall in contact with the gate dielectric film, the second sidewall opposite to the first sidewall in the second horizontal direction and in contact with the upper conductive plug,
a top surface of each of the first ferroelectric layer and the second ferroelectric layer is in contact with the insulating capping pattern, and a bottom surface of each of the first ferroelectric layer and the second ferroelectric layer is in contact with the lower conductive plug.

19. The integrated circuit device of claim 18, wherein the ferroelectric layer includes hafnium zirconium oxide (HfZrO₂).

20. The integrated circuit device of claim 18, wherein
the first ferroelectric layer includes a first lower ferroelectric layer and a first upper ferroelectric layer spaced apart from the first lower ferroelectric layer in a vertical direction, the vertical direction extending perpendicular to the main surface of the substrate, and
the second ferroelectric layer includes a second lower ferroelectric layer and a second upper ferroelectric layer spaced apart from the second lower ferroelectric layer in the vertical direction.
